(19) United States
(12) Patent Application Publication
(10) Pub. No.: US 2002/0088635 A1
(43) Pub. Date: Jul. 11, 2002

(54) Tight conductor leadthrough through a plastic wall

(76) Inventor: Karl Smirra, Wasserburg (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/066,873

(22) Filed: Feb. 4, 2002

Related U.S. Application Data
(63) Continuation of application No. PCT/DE00/02504, filed on Jul. 28, 2000.

(30) Foreign Application Priority Data
Aug. 3, 1999 (DE) 199 36 370.6

(51) Int. Cl. H01L 23/02

(52) U.S. Cl. 174/52.4

(57) ABSTRACT

A leadthrough configuration has a metallic conductor embedded into a plastic wall. The plastics material and the conductor material have different coefficients of thermal expansion. The conductor is formed in such a way that, when there is a change in temperature, at least one portion remains in the leadthrough path, wherein oppositely directed sealing forces act on the conductor.

### CROSS-REFERENCE TO RELATED APPLICATION

This application is a continuation of copending International Application No. PCT/DE00/02504, filed Jul. 28, 2000, which designated the United States.

### BACKGROUND OF THE INVENTION

Field of the Invention

The invention relates to a configuration for a tight leadthrough for an electrical conductor through a plastic wall wherein the conductor is embedded into the plastic wall and the plastics material and the metal material of the conductor have different coefficients of thermal expansion. The invention also pertains to a configuration for the tight leading of a metallic conductor through a plastic wall wherein the conductor is provided with at least two radial disk elements, which are arranged with an axial spacing. Finally, the invention pertains to a method of producing a tight leadthrough for a metallic conductor through a plastic wall.

With plastic housings it is necessary in many technical applications to lead electrical conductors tightly through a wall of the housing.

In this connection, it has become known from U.S. Pat. No. 5,728,964 to provide conductors as press-in pins with a serrated profile in the press-in region and insert them through bores in the plastic wall. What is disadvantageous about this solution is the great assembly effort and also the fact that contacting structures can only be provided on the inserted-through end of the press-in pin after it has been inserted through.

A further possibility for leading conductors through plastic housing walls is for the conductors to be embedded into the wall while the wall is being produced. U.S. Pat. No. 5,737,188 and German patent application DE 195 15 622 describe a control module for a motor vehicle wherein electrical conductors in the form of a leadframe are integrated into the housing wall by encapsulation in plastic. This method is extremely well suited for mass production and makes it possible to produce low-cost conductor leadthroughs. However, the achievement of a tightness of the leadthrough which is adequate for practical requirements may be problematical. The cause for this is that, when there are temperature changes, owing to different coefficients of thermal expansion of the metal conductor and the encapsulated plastic housing, the adhesion between the conductor and the plastic can rupture when there are temperature changes, which leads to the housing not being tight.

Specifically when encapsulated conductor leadthroughs of this type are used in integrated engine or transmission control devices, aggravated conditions exist, since such device modules have to be operated in a wide temperature range and must remain tight over years. Added to this is the fact that an extremely high immunity to failure is required, since, in the event of a repair, the subassembly concerned (engine or transmission) must be opened, which involves considerable effort and costs.

German Patent DE 33 08 332 C2 provides a description of a pressuretight and vacuumtight leadthrough, which can be used under exposure to changing temperatures. The leadthrough has a conductor designed as a single-axis round part, which is guided through a casting resin block. Circumferential grooves are provided on the portion of the conductor which runs in the casting resin block. It is formed in this way both for the composite strength and the tightness of the leadthrough.

German published patent application DE 43 30 977 A1 describes a housing made of plastic through which electrical conductors are led. In the region where they leave the housing wall, the conductors are angled away into the interior space of the housing and are surrounded in this region by a sealing compound which has been filled into a recess provided at the conductor outlet.

German Patent DE 1 161 969 describes a configuration for sealing electrical conductors in a head part. The conductor has a step-shaped bend.

### SUMMARY OF THE INVENTION

It is accordingly an object of the invention to provide an assembly for leading a metallic conductor through a plastic wall, which overcomes the above-mentioned disadvantages of the heretofore-known devices and methods of this general type and which can be created at low cost and exhibits good sealing properties, in particular even when great changes in temperature occur. Furthermore, the invention is aimed at providing a method of producing a leadthrough configuration of this type which can be performed at low cost.

With the foregoing and other objects in view there is provided, in accordance with the invention, a leadthrough configuration, comprising:

a plastic wall formed of a plastic material having a first coefficient of thermal expansion;

a metallic conductor formed of a metal having a second coefficient of thermal expansion different from the first coefficient of thermal expansion, the conductor being embedded in the plastic wall and extending along a leadthrough path; and

the conductor having a bent profile configured such that, upon a change in temperature, at least one portion of the metallic conductor remains in the leadthrough path wherein oppositely directed sealing forces act on the conductor.

With the above and other objects in view there is also provided, in accordance with the invention, a leadthrough configuration, comprising:

a plastic wall;

a metallic conductor extending through the wall in tight sealing fashion, the conductor having at least two axially spaced, radial disk elements; and

each the radial disk element being formed on both sides with in each case two raised, radially spaced-apart peripheral cross-pieces.

Again with the above and other objects in view there is further provided, in accordance with the invention, a method of producing a tight leadthrough for a metallic conductor through a plastic wall, which comprises:

providing a metal conductor formed of a material having a coefficient of thermal expansion different from a plastics material of the plastic wall;

embedding the conductor, preferably by encapsulation, into the plastic wall to extend along a leadthrough path; and

prior to embedding, bending the conductor to give the conductor a form such that, after embedding into the plastic material, and upon a change in temperature, at least a portion of the conductor remains in the leadthrough path, wherein oppositely directed sealing forces act on the conductor.

The idea on which the invention is based is to use the difference between the thermomechanical material properties of the conductor and the plastics material, which in the case of known arrangements leads to leakages, to achieve sealing forces by forming the conductor in a suitable way. A first aspect of the invention is, for this purpose, to provide a conductor with a bent profile. The plastics material constricts the conductor, while exerting the oppositely directed sealing forces, at least in a portion of the leadthrough path, the leadthrough path being sealed as a result. It goes without saying that a number of such “sealing points” may be created in the leadthrough path and that the position of the sealing point(s) may change with the ambient temperature.

The profile of the conductor in a first plane preferably comprises at least two oppositely curved bends. As a result, a sealing of conductor walls extending essentially perpendicularly to the first plane is achieved in the connecting region of the two bends.

A likewise preferred, further possibility for achieving a sealing of conductor walls oriented essentially perpendicularly to the first plane is that the profile of the conductor in the first plane comprises a (single) bend, and that the bend is surrounded in its outer region, at least in certain portions, by an essentially rigid counterpressure element, in particular a capsule. Here, too, a pressing force on the inner side wall of the conductor is produced in the region of the bend. The counterpressing force, acting on the opposite (outer) conductor side wall, is not produced here—unlike in the case of the first solution—by a second, oppositely curved bend of the conductor, but by the rigid counterpressure element.

For sealing conductor walls extending essentially parallel to the first plane, the conductor may be provided with at least two pairs of sealing projections, which are spaced apart in the axial direction, directed away from each other and extend in a direction perpendicular to the first plane.

A second aspect of the invention, which can also be combined with the first aspect, is wherein the conductor is provided with at least two radial disk elements, which are arranged with an axial spacing and are provided on both sides with raised, radially spaced-apart peripheral cross-pieces. Here, too, the principle for achieving tightness consists in that a pressure build-up takes place between the two radial disk elements in the plastics material and between the radial disk elements and, as a result, tight metal-plastic contact regions are produced on the mutually facing sides of the radial disks.

A particularly expedient variant of the invention is wherein a plurality of conductors are grouped together in the form of a leadframe.

In addition to its suitability for being integrated into mass production procedures, the method according to the invention has the advantage that the conductors can be suitably worked at their conductor ends, later protruding out of the wall, even before they are embedded into the plastics material, so that there is no need for laborious reworking of the conductor ends in the housing assembly.

Other features which are considered as characteristic for the invention are set forth in the appended claims.

Although the invention is illustrated and described herein as embodied in a tight conductor leadthrough through a plastic wall, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic sectional view of a conductor embedded in a plastic wall with a single rectangular bend;

FIG. 2 is a perspective view of a conductor with three rectangular bends according to a first embodiment of the invention;

FIG. 3 is a schematic sectional representation of the conductor of FIG. 2 embedded in a plastic wall after an increase in temperature has occurred;

FIG. 4 is a schematic longitudinal sectional view of a conductor portion with three pairs of sealing projections;

FIG. 5 is a schematic sectional representation of a conductor embedded into a plastic wall with an encapsulated rectangular bend according to a variant of the first embodiment;

FIG. 6 is a schematic representation of a conductor embedded in a plastic wall with two radial disk elements according to a second embodiment of the invention; and

FIG. 7 is a schematic representation of a housing portion of a motor-vehicle control device with a line leadthrough according to the variant of the first embodiment represented in FIG. 5.

### DESCRIPTION OF THE PREFERRED EMBODIMENTS

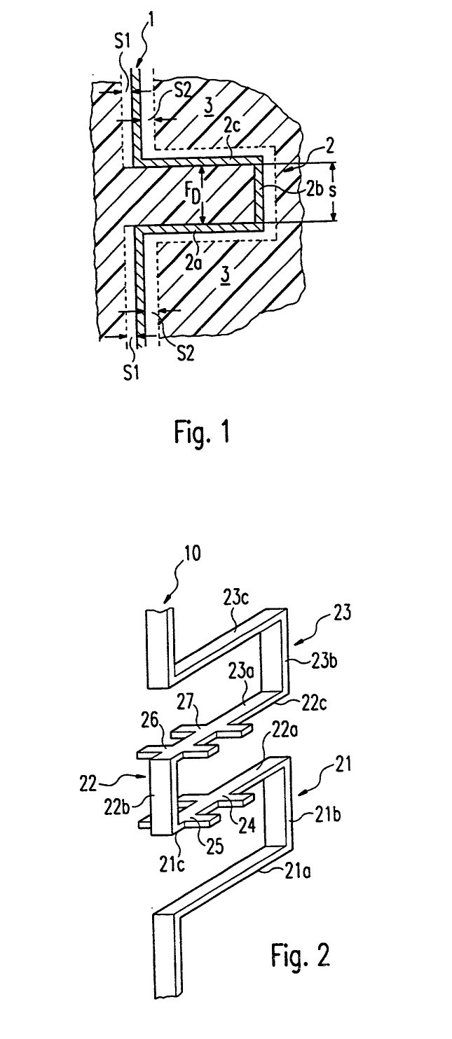

Referring now to the figures of the drawing in detail and first, particularly, to FIG. 1 thereof, the illustration serves for explaining the basic principle of the invention by the example of a conductor 1 with a single rectangular bend 2. The bend 2 of the conductor is provided by the bend legs 2a, 2c and the bend end region 2b.

It is assumed that the conductor 1 is embedded in a plastics material 3 without any gaps by an encapsulating operation. The plastics material 3, for example nylon 66, may have a coefficient of thermal expansion α=60×10⁻⁶ K⁻¹. The conductor 1 consists, for example, of copper and has a coefficient of thermal expansion of approximately α=17×10⁻⁶ K⁻¹.

As a result of an increase in temperature, the state represented in FIG. 1 would be obtained. On account of a greater thermal expansion of the plastic 3, gaps S1, S2 form at the longitudinal regions 4a and 4b of the conductor 1, on both sides of the latter, lying in front of and behind the bend 2, and in the case of a customary linear type of construction would have the consequence that the leadthrough is not tight.

A partial sealing of the leadthrough is indeed achieved by the single bend 2, that is a sealing of the gap S1. The reason for this is that the greater thermal expansion of the plastic spreads out the conductor 1 in the concave region of the bend 2, i.e. produces a pressing force (sealing force) F_{D} here. This pressing force F_{D} is all the greater, the greater the dimension s, which denotes the distance between the two bend legs 2a, 2c. In the convex region of the bend 2, the conductor 1 is exposed, however, i.e. the gap S2 is created. To close the gap S2, further measures are required, which are explained in conjunction with the figures below.

FIG. 2 shows a conductor 10, which differs essentially from the conductor 1 shown in FIG. 1 in that it has three bends 21, 22, 23 with opposite curvatures. The legs of the bends 21, 22, 23 are denoted by the reference numerals 21a, 21c, 22a, 22c, 23a, 23c, the legs 21c, 22a of the first and second bends and the legs 22c, 23a of the second and third bends coinciding. The end regions of the bends 21, 22, 23 are denoted by the reference numerals 21b, 22b and 23b.

The conductor 10 is provided on the legs 22a with two crosspieces 24, 25 and on the leg 22c with two cross-pieces 26, 27. The cross-pieces 24, 25, 26, 27 lie in a plane perpendicular to the conductor plane (first plane), defined by the bends 21, 22, 23.

The conductor 10 has a rectangular cross section. It can be produced in a simple way in the extended form as a punched part and subsequently be brought into the form represented in FIG. 2 by bending.

FIG. 3 shows a sectional representation along the conductor track plane (first plane) of the conductor 10 embedded in the plastic wall 3 after an increase in temperature has occurred. As already explained with reference to FIG. 1, gaps S1, S2 form on both sides of the end longitudinal regions 14a, 14b of the conductor 10.

Furthermore, on account of the material expansion of the plastic 2, a pressure build-up occurs in the regions of plastics material bordered by the bends 21, 22, 23 and a spreading-apart of the legs 21a, 21c; 22a, 22c; 23a, 23c occurs. Since the regions of plastics material bordered by the bends 21, 22, 23 are neighboring, the two legs 21c, 22a and 22c, 23a are subjected to sealing forces F_{D} on both sides, i.e. the regions of plastics material are pressed on both sides against the conductor 10 in the region of the two legs. This leads to the sealing of the conductor 1 in the first plane.

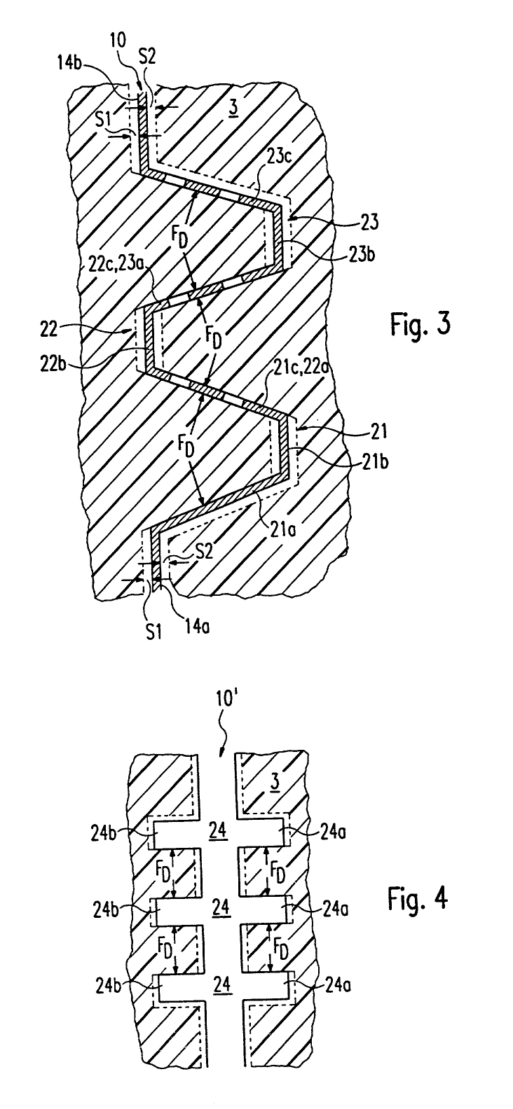

For applications without very great tightness requirements, the sealing in the first plane may already be sufficient. However, a sealing in the (second) plane perpendicular to the conductor plane is expediently also to be provided. This is accomplished by the cross-pieces 24, 25, 26, 27. It is based on the same principle and is explained with reference to FIG. 4. FIG. 4 shows a conductor portion 10′, which differs from the legs 21c, 22a and 22c, 23a represented in FIG. 2 only in that it is not provided with two but three cross-pieces 24. The cross-piece ends 24a and 24b respectively form neighboring, axially spaced-apart sealing projections, between which the sealing forces F_{D} directed in opposition to one another build up in the way already explained when there is an increase in temperature, and as a result seal the leadthrough path in the second plane.

FIGS. 2 to 4 reveal that a conductor with two oppositely curved bends and two cross-pieces on the common leg of the two bends is sufficient for complete sealing of the leadthrough. By arranging further bends and/or conductor portions 10′ with cross-pieces 24 in series, however, the reliability of the sealing function can be considerably increased.

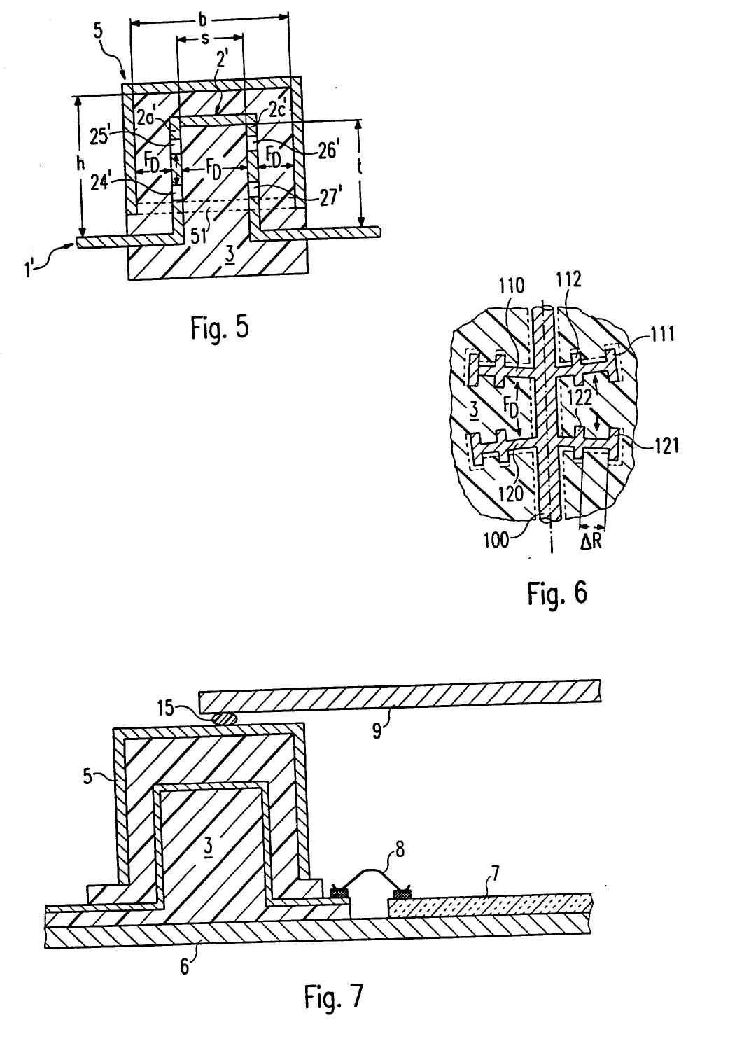

FIG. 5 shows a variant of the first embodiment explained above. In the case of this variant, the conductor 1′ has, by analogy with the conductor 1, only a single bend 2′. Furthermore, the legs 2a′, 2c′ of the bend 2′ are provided in the way already described with in each case two cross-pieces 24′, 25′ and 26′, 27′, spaced apart from one another. The bend 2′ is completely encapsulated in the plastics material 3, which forms the wall. This plastic wall is enclosed by a rigid cap 5, which may be made of metal, for example of steel, with a coefficient of thermal expansion of α=12×10⁻⁶ K⁻¹.

The cap 5 may be integrated in the assembly in one operation during the encapsulation of the conductor (leadframe) 1′ or be subsequently mounted on the plastic wall in the manner of a frame. Due to the lower thermal expansion of the material of the cap in comparison with the plastics material 3, pressing forces F_{D} build up in the regions of plastics material between the legs 2a′, 2c′ of the bend 2′ and the side walls of the cap when there is an increase in temperature, said forces being directed oppositely to the pressing forces F_{D} occurring within the bend and consequently bringing about sealing of the leadthrough both in the region of the convex conductor wall regions and in the region of the concave conductor wall regions.

The sealing of the second plane, perpendicular to the conductor track plane represented by the plane of the paper, is achieved in the way already described by the interaction of neighboring cross-pieces 24′, 25′ and 26′, 27′. To increase the sealing effect, here, too, a number of sealing cells of this type, arranged in series with one another, may be provided.

The maximum achievable sealing effect depends, inter alia, on the choice of material with respect to the conductor 1′, the plastic 3 and the cap 5 and, in particular, the rigidity of the cap. In addition, it is significantly influenced by the geometry of the leadthrough configuration. The sealing force is all the greater, the greater the bend width s and the bend amplitude t, since with a greater length of s, t a correspondingly greater absolute expansion of these regions is achieved, which in turn causes correspondingly higher pressing forces F_{D}.

The rigidity of the cap may also be increased by structural design measures, such as for example the presence of a connecting part 51 between the side walls of the cap 5. It is further influenced by the cap width b and the cap height h.

Since the pressing forces occurring between the conductor bend 2′ and the cap 5 also act on the inner side of the cap 5, the cap 5 is also sealed on the basis of the mechanism already described.

FIG. 6 shows a second embodiment of a leadthrough configuration according to the invention. The conductor 100 is designed as a round part and has two radial disk elements 110, 120, arranged spaced-apart in the axial direction. Each radial disk element 110, 120 is configured in an optional way with at least two radially spaced-apart cross-pieces 111, 112 and 121, 122. The peripheral cross-pieces 111, 112, 121, 122 protrude on both sides from the disk surfaces of the radial disk elements 110, 120. The conductor 100 is embedded in the plastics material 3 in a manner according to the previous description.

Sealing in the axial direction of the conductor 100 is ensured by the radial disk elements 110, 120, since a sealing force F_{D} acting axially in the direction of the double-headed arrows builds up in the region of plastics material lying between, on the basis of the principle already described. The level of the sealing force F_{D} increases with the axial spacing of the radial disk elements 110, 120. The optional peripheral crosspieces 111, 112, 121, 122 ensure additional sealing of the radial disk elements 110, 120 in the radial direction. The level of the radial sealing force is proportional to the distance of the peripheral cross-pieces 111, 112, 121, 122 from the conductor axis and proportional to the radial distance ΔR of the peripheral cross-pieces 111, 112 and 121, 122 from one another.

The description of FIGS. 1-6 above explains the invention on the basis of an increase in temperature and where the metal components have a lower coefficient of thermal expansion than the plastic components. The principle according to the invention also works, however, when there is a decrease in temperature and/or a coefficient of thermal expansion of metal greater than that of the plastic. In this case, the sealing does not take place in the convex region but in the concave region of a bend.

FIG. 7 shows a partial sectional representation of a motor-vehicle control device for installation in an engine or transmission housing. The control device has an aluminum base plate 6, on which a ceramic leadframe 7 is fastened. Control electronics are provided on the leadframe 7.

In the example represented here, the side wall region of the motor-vehicle control device is provided by the encapsulated wall leadthrough shown in FIG. 5. A housing cover 9 of the control device is coupled to the upper side of the cap 5 in a liquid-tight manner by means of a form seal 15.

In an analogous way, the arrangements shown in the other FIGS. 2-6 and combinations of the same may also be used for the tight leading through of current-carrying and signal-carrying lines in a motor-vehicle control device.

I claim:

1. A leadthrough configuration, comprising:
a plastic wall formed of a plastic material having a first coefficient of thermal expansion;
a metallic conductor formed of a metal having a second coefficient of thermal expansion different from the first coefficient of thermal expansion, said conductor being embedded in said plastic wall and extending along a leadthrough path; and
said conductor having a bent profile configured such that, upon a change in temperature, at least one portion of said metallic conductor remains in the leadthrough path wherein oppositely directed sealing forces act on said conductor.

2. The configuration according to claim 1, wherein said profile of said conductor in a first plane includes at least two oppositely curved bends.

3. The configuration according to claim 2, wherein said conductor is formed with at least two pairs of sealing projections, said sealing projections are spaced apart in an axial direction, directed away from each other, and extend in a direction perpendicular to the first plane.

4. The configuration according to claim 2, wherein said bends have a rectangular profile.

5. The configuration according to claim 1, wherein said profile of said conductor in a first plane includes one bend, and wherein a rigid counter-pressure element surrounds said bend at least in certain portions of an outer region thereof.

6. The configuration according to claim 5, wherein said counterpressure element is a capsule.

7. The configuration according to claim 5, wherein said conductor is formed with at least two pairs of sealing projections, said sealing projections are spaced apart in an axial direction, directed away from each other, and extend in a direction perpendicular to the first plane.

8. The configuration according to claim 5, wherein said bend or the bends have a rectangular profile.

9. The configuration according to claim 1, wherein said conductor has a rectangular cross-sectional profile.

10. A leadthrough configuration, comprising:
a plastic wall;
a metallic conductor extending through said wall in tight sealing fashion, said conductor having at least two axially spaced, radial disk elements; and
each said radial disk element being formed on both sides with in each case two raised, radially spaced-apart peripheral cross-pieces.

11. The configuration according to claim 10, wherein said conductor is one of a plurality of conductors grouped together in form of a leadframe.

12. A method of producing a tight leadthrough for a metallic conductor through a plastic wall, which comprises:
providing a metal conductor formed of a material having a coefficient of thermal expansion different from a plastics material of the plastic wall;
embedding the conductor into the plastic wall to extend along a leadthrough path; and
prior to embedding, bending the conductor to give the conductor a form such that, after embedding into the plastic material, and upon a change in temperature, at least a portion of the conductor remains in the leadthrough path, wherein oppositely directed sealing forces act on the conductor.

13. The method according to claim 12, wherein the embedding step comprises encapsulating the metal conductor with plastics material.
